(19) United States
(12) Patent Application Publication
(10) Pub. No.: US 2023/0240154 A1
(43) Pub. Date: Jul. 27, 2023

(54) METHODS FOR FABRICATING SUPERCONDUCTING INTEGRATED CIRCUITS

(71) Applicant: D-WAVE SYSTEMS INC., Burnaby (CA)

(72) Inventors: Byong Hyop Oh, San Jose, CA (US); Eric G. Ladizinsky, Manhattan Beach, CA (US); J. Jason Yao, San Ramon, CA (US)

(21) Appl. No.: 18/010,283

(22) PCT Filed: Jun. 22, 2021
(86) PCT No.: PCT/US2021/038519

§ 371 Date: Dec. 14, 2022

Related U.S. Application Data
(60) Provisional application No. 63/042,865, filed on Jun. 23, 2020.

(51) Int. Cl. H10N 60/01; H10N 60/80

(52) U.S. Cl. CPC H10N 60/01; H10N 60/80

(57) ABSTRACT

Methods of forming superconducting integrated circuits are discussed. The method includes depositing a first superconducting metal layer to overlie at least a portion of a substrate, depositing a dielectric layer to cover a first region of the first superconducting metal layer, pattering the dielectric layer to expose at least a portion of the first region of the first superconducting metal layer and form an opening, and depositing a second superconducting metal layer at an ambient temperature that is less than a melting temperature of the second superconducting metal layer such that the second superconducting metal layer fills the opening and conductively contacts the at least a portion of the first region of the first superconducting metal layer.

### FIELD

This disclosure generally relates to methods for fabrication of superconducting integrated circuits, and in particular relates to systems and methods for forming components of superconducting integrated circuits from aluminum.

### BACKGROUND

### Quantum Devices

Quantum devices are structures in which quantum mechanical effects are observable. Quantum devices include circuits in which current transport is dominated by quantum mechanical effects. Such devices include spintronics and superconducting circuits. Both spin and superconductivity are quantum mechanical phenomena. Quantum devices can be used for measurement instruments, in computing machinery, and the like.

### Quantum Computation

A quantum computer is a system that makes direct use of at least one quantum-mechanical phenomenon, such as superposition, tunneling, and entanglement, to perform operations on data. The elements of a quantum computer are qubits. Quantum computers can provide speedup for certain classes of computational problems such as computational problems simulating quantum physics.

### Superconducting Processor

A quantum processor may take the form of a superconducting processor. However, superconducting processors may include processors that are not intended for quantum computing. For instance, some implementations of a superconducting processor may not focus on quantum effects such as quantum tunneling, superposition, and entanglement but may rather operate by emphasizing different principles, such as for example the principles that govern the operation of classical computer processors. However, there may still be certain advantages to the implementation of such superconducting “classical” processors. Due to their natural physical properties, superconducting classical processors may be capable of higher switching speeds and shorter computation times than non-superconducting processors, and therefore it may be more practical to solve certain problems on superconducting classical processors. The present systems and methods are particularly well-suited for use in fabricating both superconducting quantum processors and superconducting classical processors.

### Superconducting Qubits

Superconducting qubits are a type of superconducting quantum device that may be included in a superconducting integrated circuit. Superconducting qubits may be separated into several categories depending on the physical property used to encode information. For example, superconducting qubits may be separated into charge, flux, and phase devices. Charge devices store and manipulate information in the charge states of the device. Flux devices store and manipulate information in a variable related to the magnetic flux through some part of the device. Phase devices store and manipulate information in a variable related to the difference in superconducting phase between two regions of the device. Recently, hybrid devices using two or more of charge, flux and phase degrees of freedom have been developed. Superconducting qubits commonly include at least one Josephson junction. A Josephson junction is a small interruption in an otherwise continuous superconducting current path and is typically realized by a thin insulating barrier sandwiched between two superconducting electrodes. Thus, a Josephson junction may be formed as a three-layer or “trilayer” structure. Superconducting qubits are further described in, for example, U.S. Pat. 7,876,248, U.S. Pat. 8,035,540, and U.S. Pat. 8,098,179.

### Integrated Circuit Fabrication

An integrated circuit is also referred to in the present application as a chip, and a superconducting integrated circuit is also referred to in the present application as a superconducting chip.

Traditionally, the fabrication of superconducting integrated circuits has not been performed at state-of-the-art semiconductor fabrication facilities. This may be due to concern that some of the materials used in superconducting integrated circuits may contaminate the semiconductor facilities. For instance, gold may be used as a resistor in superconducting circuits, but gold may contaminate a fabrication tool used to produce complementary metal-oxide-semiconductor (CMOS) wafers in a semiconductor facility.

Superconductor fabrication has typically been performed in research environments where standard industry practices could be optimized for superconducting circuit production. Superconducting integrated circuits are often fabricated with tools that are traditionally used to fabricate semiconductor chips or integrated circuits. Due to issues unique to superconducting circuits, not all semiconductor processes and techniques are necessarily transferrable to superconductor chip manufacture. Transforming semiconductor processes and techniques for use in superconductor chip and circuit fabrication often requires changes and fine adjustments. Such changes and adjustments typically are not obvious and may require a great deal of experimentation. The semiconductor industry faces problems and issues not necessarily related to the superconducting industry. Likewise, problems and issues that concern the superconducting industry are often of little or no concern in standard semiconductor fabrication.

Any impurities within superconducting chips may result in noise which may compromise or degrade the functionality of the superconducting chip. Noise may also compromise or degrade the functionality of individual devices such as superconducting qubits. Since noise is a serious concern to the operation of quantum computers, measures should be taken to reduce noise wherever possible.

The foregoing examples of the related art and limitations related thereto are intended to be illustrative and not exclusive. Other limitations of the related art will become apparent to those of skill in the art upon a reading of the specification and a study of the drawings.

### BRIEF SUMMARY

According to an aspect, there is provided a method of forming a superconducting integrated circuit for a quantum processor, the method comprising depositing a first superconducting metal to form a first superconducting metal layer that overlies at least a portion of a substrate, the first superconducting metal layer comprising an upper surface having a first region, depositing a dielectric layer to cover the first region of the first superconducting metal layer, patterning the dielectric layer to expose at least a portion of the first region of the first superconducting metal layer and form an opening, and depositing a second superconducting metal at an ambient temperature that is less than a melting temperature of the second superconducting metal such that the second superconducting metal fills the opening to form a connect that conductively contacts the at least a portion of the first region of the first superconducting metal layer and forms a second superconducting metal layer that overlies the dielectric layer and the connect.

According to other aspects, the method may further comprise depositing an adhesion layer to line at least the sides of the opening prior to depositing the second superconducting metal, planarizing the first superconducting metal layer, planarizing the second superconducting metal layer, planarizing the second superconducting metal layer may comprise chemical-mechanical polishing (CMP), patterning the dielectric layer to form an opening may comprise patterning the dielectric layer to form an opening with a dimension of greater than 0.1 micron, depositing the second superconducting metal may comprise depositing aluminum, depositing a second superconducting metal at an ambient temperature that is less than a melting temperature of the second superconducting metal may comprise depositing at an ambient temperature that is less than 650° C., or at an ambient temperature that is between 100° C. and 520° C., depositing a second superconducting metal at an ambient temperature that is less than a melting temperature of the second superconducting metal may comprise depositing a first portion at an ambient temperature that is between 100° C. and 300° C. and depositing a second portion at an ambient temperature that is between 450° C. and 650° C., depositing the second superconducting metal may comprise depositing aluminum by physical vapor deposition (PVD), and depositing the first superconducting metal comprises depositing aluminum.

According to other aspects, depositing a first superconducting metal may comprise depositing a first wiring layer and depositing a second superconducting metal may comprise depositing a via and a second wiring layer. The method may further comprise after depositing the first superconducting metal layer, patterning the first superconducting metal layer to form an additional opening, depositing an additional dielectric layer to fill the additional opening, and depositing the dielectric layer to cover the first region of the first superconducting metal layer and a top surface of the additional dielectric layer, may further comprise prior to patterning the first superconducting metal layer, depositing a polish stop layer over the at least a portion of the first superconducting metal layer and patterning the first superconducting metal layer may further comprise patterning the first superconducting metal layer and the polish stop layer, may further comprise after depositing the additional dielectric layer to fill the additional opening, planarizing the additional dielectric layer to have a top surface level with a top surface of the polish stop layer and removing the polish stop layer, may further comprise depositing a second polish stop layer over at least a portion of the second superconducting metal layer, patterning the second polish stop layer and the second superconducting metal layer to form a third opening, and depositing a third dielectric layer to fill the third opening, and may further comprise depositing a superconducting barrier layer overlying the second superconducting metal layer and patterning the second superconducting metal layer and the superconducting barrier layer.

According to an aspect, there is provided a method of forming a superconducting integrated circuit for a quantum processor, the method comprising depositing a first superconducting metal at a first ambient temperature that is less than a melting temperature of the first superconducting metal such that the first superconducting metal fills an opening in a first dielectric layer to form a first connect that conductively contacts a conductive layer underlying the first dielectric layer and forms a first superconducting metal layer that overlies the first dielectric layer and the first connect, depositing the first superconducting metal at a second ambient temperature that is less than a melting temperature of the first superconducting metal such that the first superconducting metal forms an adhesion layer lining an opening in a second dielectric layer and overlying the second dielectric layer, and depositing the first superconducting metal at a third ambient temperature that is less than a melting temperature of the first superconducting metal and greater than the second ambient temperature to form a fill layer to cover the adhesion layer such that the adhesion layer and the fill layer fill the opening in the second dielectric layer to form a second connect that conductively contacts a conductive layer underlying the second dielectric and form a second superconducting metal layer that overlies the second dielectric layer and the first connect.

According to other aspects, depositing a first superconducting metal at an ambient temperature that is less than a melting temperature of the first superconducting metal may comprise depositing at an ambient temperature that is between 100° C. and 300° C., depositing the first superconducting metal at a second ambient temperature that is less than a melting temperature of the first superconducting metal may comprise depositing at an ambient temperature that is between 100° C. and 300° C., and depositing the first superconducting metal at a third ambient temperature that is less than a melting temperature of the first superconducting metal may comprise depositing at an ambient temperature that is between 450° C. and 650° C.

According to an aspect, a superconducting integrated circuit can be summarized as including: a substrate; a first metal layer comprising a first metal that superconducts below a first critical temperature, the first metal layer overlying at least a portion of the substrate, the first metal layer comprising an upper surface having a first region; a dielectric layer overlying at least a portion of the first metal layer, the dielectric layer comprising an opening that exposes at least a portion of the first region of the first metal layer and has sides defined by the dielectric layer and a bottom defined by the exposed at least a portion of the first region of the first metal layer; a second metal layer comprising a second metal that superconducts below a second critical temperature, the second metal layer lining at least the sides of the opening, the second metal layer comprising an adhesion layer; and a third metal layer comprising the second metal, the third metal layer overlying at least a portion of the dielectric layer and filling the opening, the third metal layer in conductive contact with the at least a portion of the first region of the first metal layer.

According to other aspects, the second metal may comprise aluminum. The first metal may comprise aluminum. The opening may have a dimension (e.g., lateral dimension; diameter) of equal to or greater than 0.1 micron. The first metal layer may comprise a first wiring layer, and the second and third metal layers may comprise a via and a second wiring layer. An interface (e.g., transition region) between the second metal layer and the third metal layer may discernable (e.g., assessing grains via microscope, for instance assessing grain sizes), for example due to different grain sizes resulting from deposition of the material forming the layer at different temperatures at different times (e.g., sequentially).

In other aspects, the features described above may be combined together in any reasonable combination as will be recognized by those skilled in the art.

### BRIEF DESCRIPTION OF THE SEVERAL VIEWS OF THE DRAWING(S)

In the drawings, identical reference numbers identify similar elements or acts. The sizes and relative positions of elements in the drawings are not necessarily drawn to scale. For example, the shapes of various elements and angles are not necessarily drawn to scale, and some of these elements may be arbitrarily enlarged and positioned to improve drawing legibility. Further, the particular shapes of the elements as drawn, are not necessarily intended to convey any information regarding the actual shape of the particular elements and may have been solely selected for ease of recognition in the drawings.

FIG. 1A is a sectional view of a portion of a superconducting integrated circuit after a metal deposition on a substrate.

FIG. 1B is a sectional view of the portion of the superconducting integrated circuit of FIG. 1A after a dielectric deposition stage.

FIG. 1C is a sectional view of the portion of the superconducting integrated circuit of FIG. 1B after a patterning stage.

FIG. 1D is a sectional view of the portion of the superconducting integrated circuit of FIG. 1C during a first stage of a metal deposition and reflow process.

FIG. 1E is a sectional view of the portion of the superconducting integrated circuit of FIG. 1D during a second stage of a metal deposition and reflow process.

FIG. 1F is a sectional view of the portion of the superconducting integrated circuit of FIG. 1E during a third stage of a metal deposition and reflow process.

FIG. 1G is a sectional view of the portion of the superconducting integrated circuit of FIG. 1F during a fourth stage of a metal deposition and reflow process.

FIG. 1H is a sectional view of the portion of the superconducting integrated circuit of FIG. 1G during a fifth stage of a metal deposition and reflow process.

FIG. 1I is a sectional view of the portion of the superconducting integrated circuit of FIG. 1H after an optional planarization stage.

FIG. 1J is a sectional view of the portion of the superconducting integrated circuit of FIG. 1I after an alternative optional planarization stage.

FIG. 2A is a sectional view of a portion of a superconducting integrated circuit having a patterned metal layer and polish stop layer.

FIG. 2B is a sectional view of the portion of the superconducting integrated circuit of FIG. 2A after deposition and planarization of a dielectric layer.

FIG. 2C is a sectional view of the portion of the superconducting integrated circuit of FIG. 2B after removal of the polish stop layer.

FIG. 2D is a sectional view of the portion of the superconducting integrated circuit of FIG. 2C after deposition and patterning of a second dielectric layer.

FIG. 2E is a sectional view of the portion of the superconducting integrated circuit of FIG. 2D after deposition and polishing of a second metal layer.

FIG. 2F is a sectional view of the portion of the superconducting integrated circuit of FIG. 2E after deposition of a polish stop layer.

FIG. 2G is a sectional view of the portion of the superconducting integrated circuit of FIG. 2F after patterning of the second metal layer and the polish stop layer.

FIG. 3A is a sectional view of an implementation of an angled superconducting via.

FIG. 3B is a sectional view of an implementation of an angled superconducting via with a superconducting adhesion layer.

FIG. 4A is a sectional view of an alternative implementation of an angled superconducting via.

FIG. 4B is a sectional view of the alternative implementation of an angled superconducting via of FIG. 4A after planarization.

FIG. 5A is a sectional view of an alternative implementation of a straight superconducting via opening.

FIG. 5B is a sectional view of the alternative implementation of a straight superconducting via of FIG. 5A after the opening has been filed by a metal layer.

FIG. 6 is a flow chart of a method for forming a superconducting integrated circuit for a quantum processor.

FIG. 7 is a flow chart of an implementation of the method for forming a superconducting integrated circuit for a quantum processor of FIG. 6.

FIG. 8 is a schematic diagram illustrating a computing system comprising a digital computer and a quantum computer that includes a superconducting integrated circuit, in accordance with the present systems and methods.

FIG. 9A is a sectional view of an implementation of a dual damascene process after patterning.

FIG. 9B is a sectional view of the implementation of a dual damascene process of FIG. 9A after a metal deposition and reflow process.

FIG. 10A is a sectional view of a portion of a superconducting integrated circuit after a metal layer deposition.

FIG. 10B is a sectional view of a portion of a superconducting integrated circuit after polishing and dielectric deposition and patterning.

FIG. 10C is a sectional view of a portion of a superconducting integrated circuit after a low temperature reflow deposition.

FIG. 10D is a sectional view of a portion of a superconducting integrated circuit during a high temperature reflow deposition.

FIG. 10E is a sectional view of a portion of a superconducting integrated circuit after a high temperature reflow deposition and polishing.

FIG. 10F is a sectional view of a portion of a superconducting integrated circuit after deposition of a passivation layer.

FIG. 10G is a sectional view of a portion of a superconducting integrated circuit after patterning.

FIG. 10H is a sectional view of a portion of a superconducting integrated circuit after removal of a passivation layer.

FIG. 10I is a sectional view of a portion of a superconducting integrated circuit having both a high temperature and a low temperature superconducting metal layer.

FIG. 11 is a flow chart of an alternative implementation of the method for forming a superconducting integrated circuit for a quantum processor of FIG. 6.

### DETAILED DESCRIPTION

In the following description, certain specific details are set forth in order to provide a thorough understanding of various disclosed implementations. However, one skilled in the relevant art will recognize that implementations may be practiced without one or more of these specific details, or with other methods, components, materials, etc. In other instances, well-known structures associated with computer systems, server computers, and/or communications networks have not been shown or described in detail to avoid unnecessarily obscuring descriptions of the implementations.

Unless the context requires otherwise, throughout the specification and claims that follow, the word “comprising” is synonymous with “including,” and is inclusive or open-ended (i.e., does not exclude additional, unrecited elements or method acts).

Reference throughout this specification to “one implementation” or “an implementation” means that a particular feature, structure, or characteristic described in connection with the implementation is included in at least one implementation. Thus, the appearances of the phrases “in one implementation” or “in an implementation” in various places throughout this specification are not necessarily all referring to the same implementation. Furthermore, the particular features, structures, or characteristics may be combined in any suitable manner in one or more implementations.

As used in this specification and the appended claims, the singular forms “a,” “an,” and “the” include plural referents unless the context clearly dictates otherwise. It should also be noted that the term “or” is generally employed in its sense including “and/or” unless the context clearly dictates otherwise.

The headings and Abstract of the Disclosure provided herein are for convenience only and do not interpret the scope or meaning of the implementations.

The various implementations described herein provide systems and methods for fabricating superconducting integrated circuits. As previously described, in the art superconducting integrated circuits tend to be fabricated in research environments outside of state-of-the-art semiconductor fabrication facilities, even though superconducting integrated circuits are typically fabricated using many of the same tools and techniques that are traditionally used in the semiconductor fabrication industry. Due to issues unique to superconducting circuits, semiconductor processes and techniques generally need to be modified for use in superconductor chip and circuit fabrication. Such modifications typically are not obvious and may require some experimentation.

A superconducting material is one which experiences a transition to superconducting behavior at a critical temperature T_{c}. Above T_{c}, the material is non-superconducting, while below Tc the material behaves as a superconductor. The critical temperature is also referred to in the present application as the transition temperature. A superconducting integrated circuit may be cooled by a refrigerator. The refrigerator may be, for example, a dilution refrigerator and/or a cryocooler, such as a pulse tube cryocooler, also referred to in the present application as a pulse tube refrigerator. A superconducting integrated circuit may be cooled to a temperature below 1 K. In some implementations, the superconducting integrated circuit is cooled to below 20 mK. In some implementations, the superconducting integrated circuit and the refrigerator are elements of a superconducting computer.

In some implementations, the superconducting computer is a superconducting quantum computer. A superconducting integrated circuit that employs multiple superconducting layers often requires superconducting interconnections between layers. These interconnections are known as “vias.” Hinode et al., Physica C 426-432 (2005) 1533-1540 discusses some of the difficulties unique to superconducting vias. In a multilayered superconducting integrated circuit, successive layers of conductive wiring are typically separated from one another by interlayer dielectrics (“ILDs”). ILDs provide structural support for the whole circuit while electrically insulating adjacent conductive layers. The thickness of an ILD determines the distance between two adjacent conductive layers in the circuit, and this distance influences, among other things, inductive and capacitive coupling between the adjacent conductive layers.

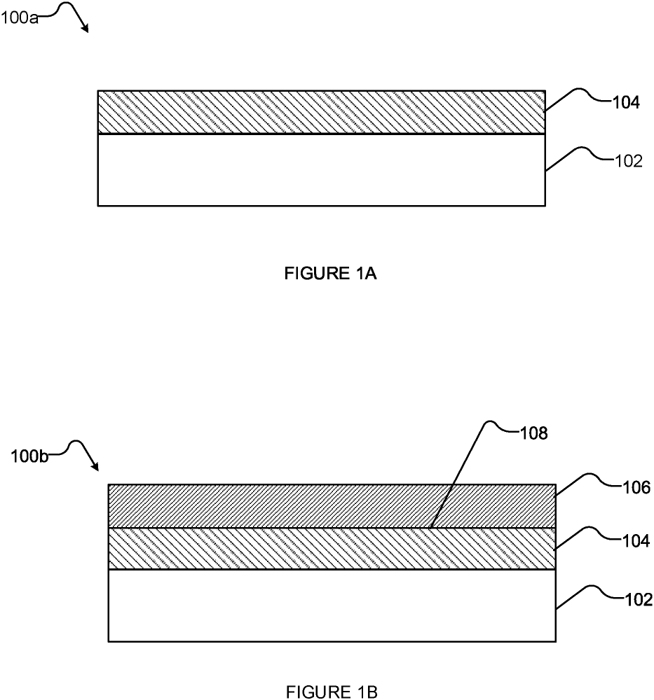

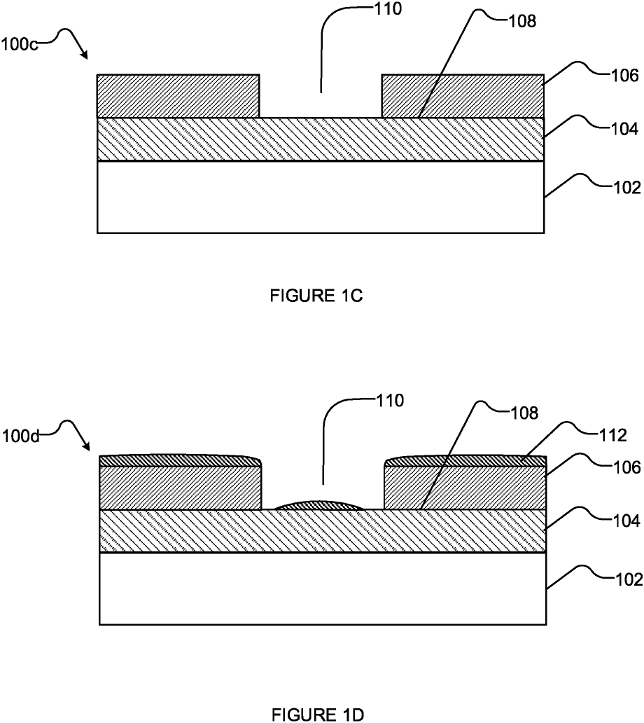

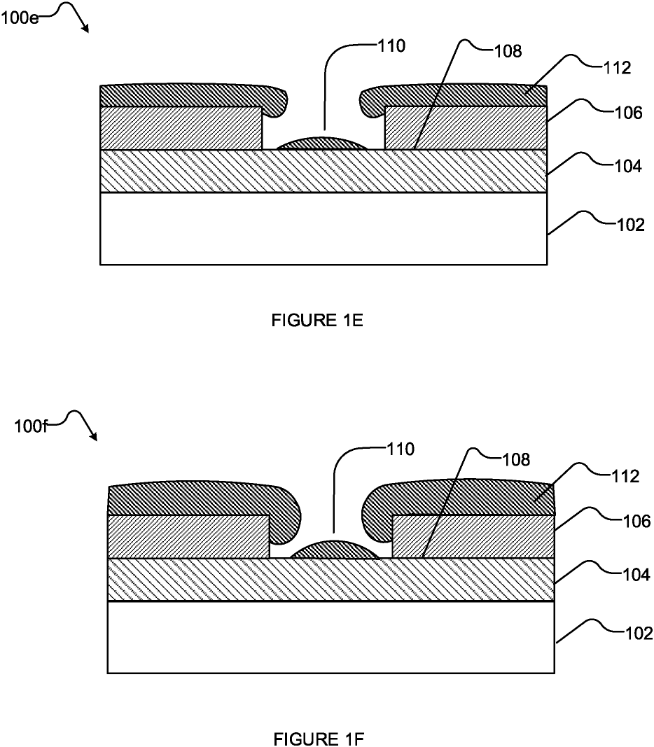

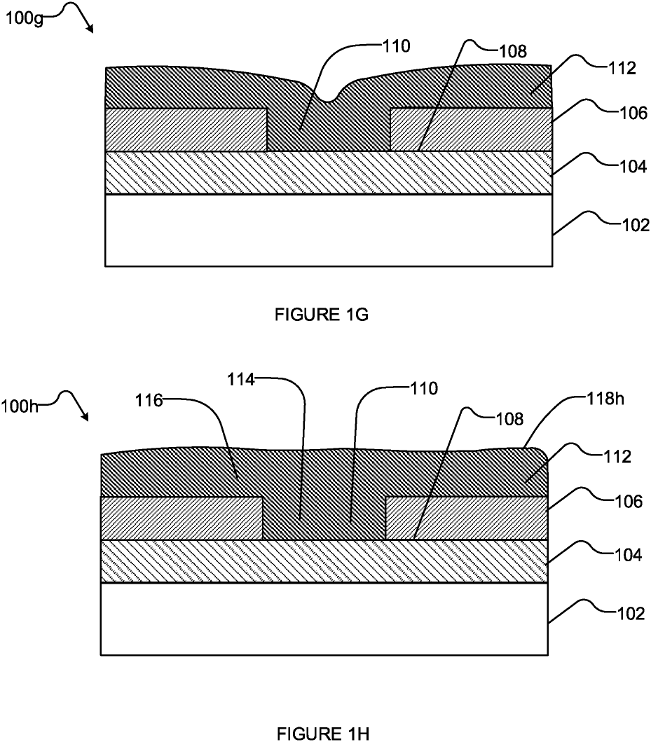

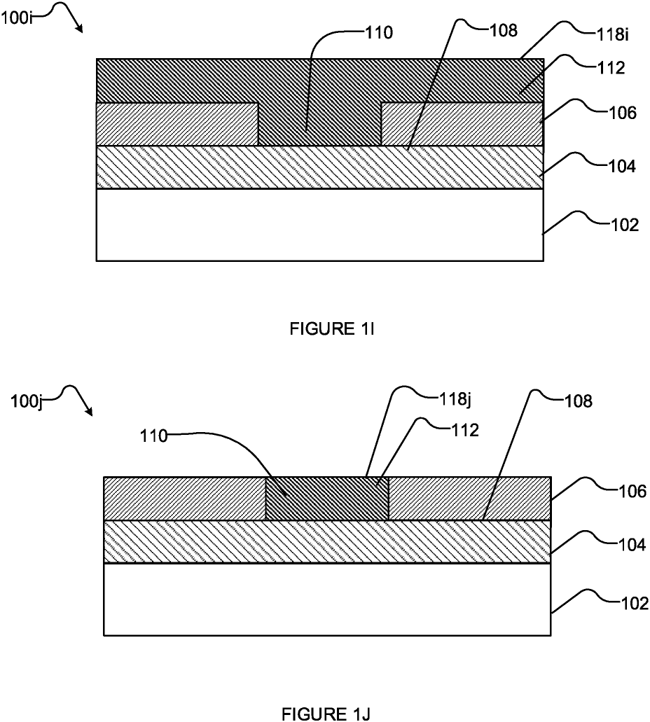

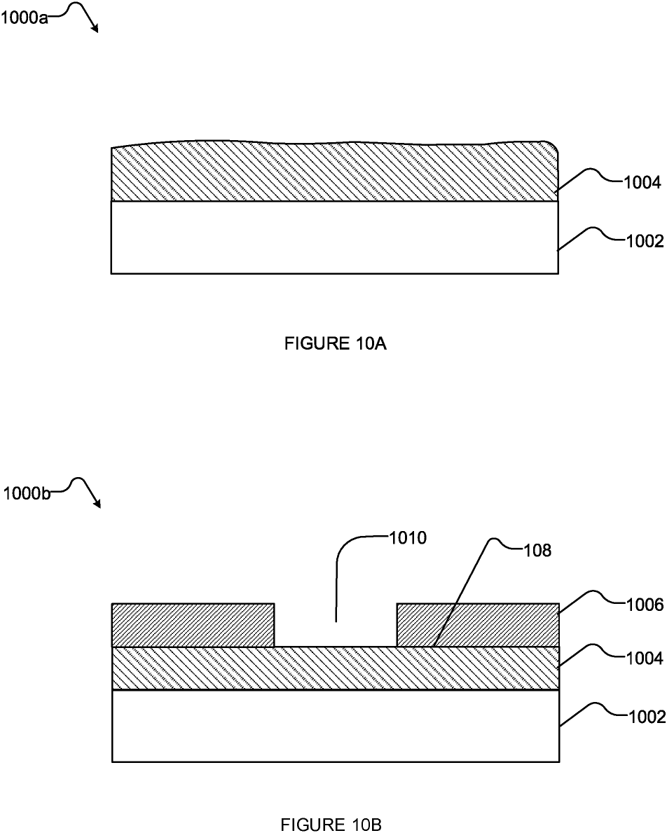

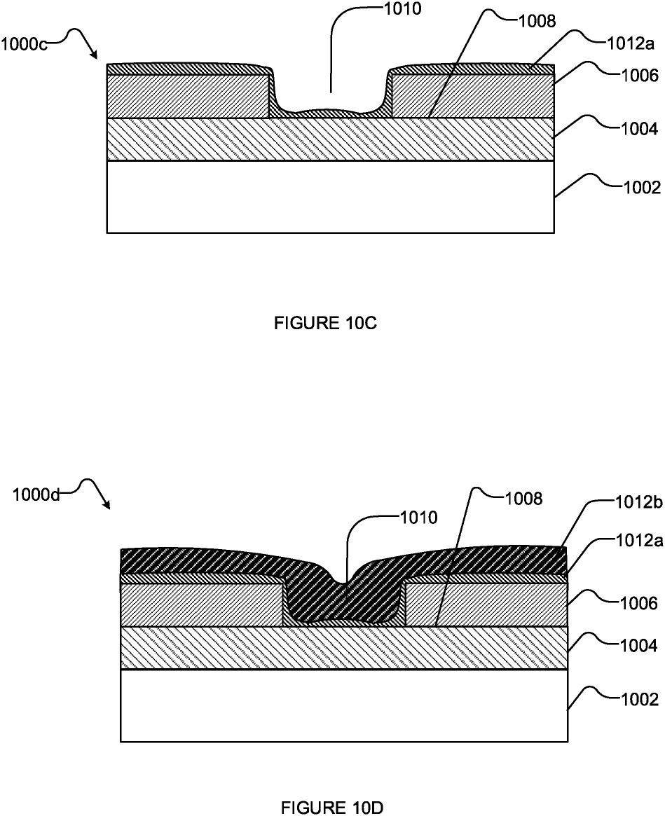

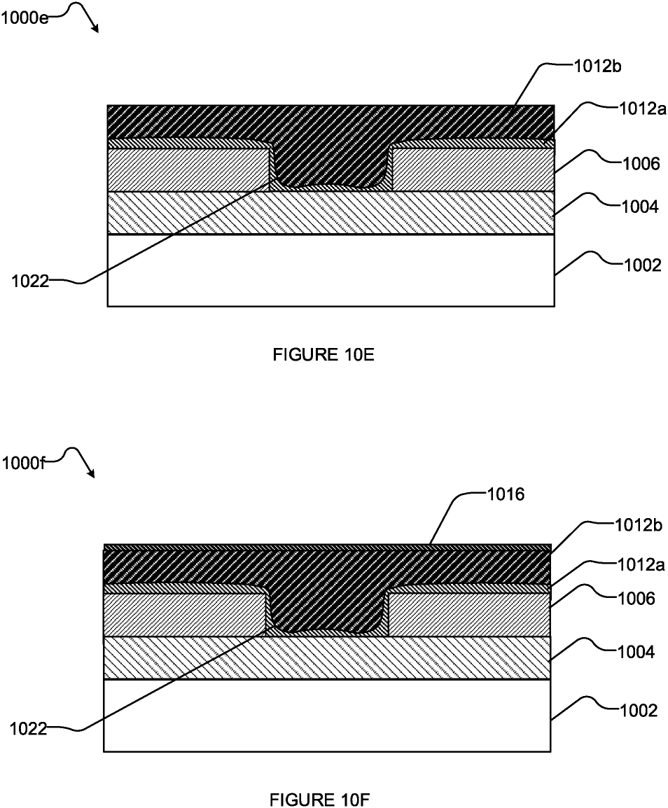

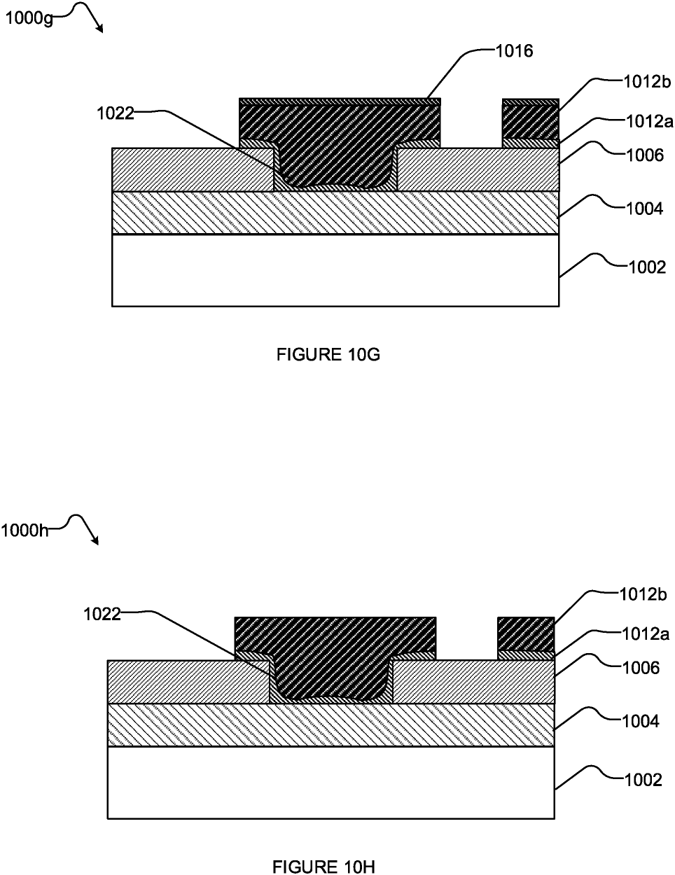

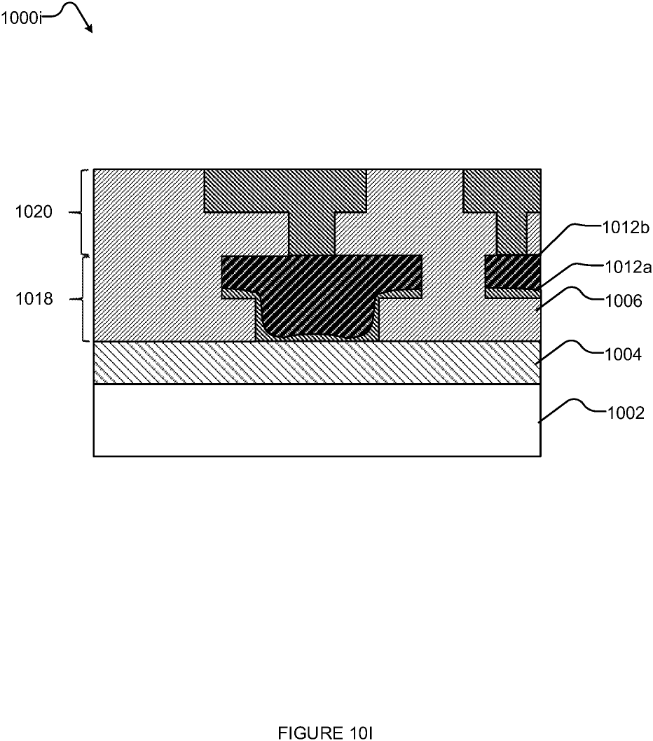

FIG. 1A shows a sectional view of a portion of a superconducting integrated circuit 100a including a substrate 102 and a first superconducting metal layer 104 deposited from a first superconducting metal to directly or indirectly overlie at least a portion of substrate 102. It will be understood that metal layer 104 may be formed directly or indirectly overlying substrate 102. As used herein, directly overlying a substrate refers to the layer being formed directly on the substrate without an intervening layer. Indirectly overlying a substrate refers to the layer being formed over at least a portion of the substrate, with at least one intervening layer between the substrate and the referenced layer. Substrate 102 may be formed from silicon, sapphire, quartz, silicon dioxide, or any similar suitable material. First superconducting metal layer 104 may be aluminum, niobium, or another appropriate superconducting metal. Unless the specific context requires otherwise, throughout this specification the terms “deposit,” “deposited,” “deposition,” and the like are generally used to encompass any method of material deposition, including but not limited to physical vapor deposition (PVD), chemical vapor deposition (CVD), plasma-enhanced PVD, plasma-enhanced CVD, and atomic layer deposition (ALD). The first superconducting metal layer may be planarized, such as with chemical mechanical planarization, as discussed in further detail below with reference to FIGS. 10A and 10B.

FIG. 1B shows a sectional view of the portion of the superconducting integrated circuit 100a of FIG. 1A after dielectric layer 106 is deposited to form superconducting integrated circuit 100b. Dielectric layer 106 is deposited to cover at least a first region of upper surface 108 of first superconducting metal layer 104. It will be understood that dielectric layer 106 may cover all or only a certain region of upper surface 108. In some implementations, dielectric material 106 may, for example, be SiO2, SiN, or any other suitable dielectric material as is known in the art. Dielectric layer 106 may be deposited by, for example, CVD, PVD, ALD, or a similar process. Dielectric layer 106 may be planarized to provide a smooth surface, if desired.

FIG. 1C shows a sectional view of the portion of the superconducting integrated circuit 100b of FIG. 1B after a patterning stage to form superconducting integrated circuit 100c. Dielectric layer 106 is patterned to expose at least a portion of the first region of the first superconducting metal layer to form aperture, recess or opening 110 (referred to collectively herein as opening 110). Opening 110 may have a dimension of greater than 0.3 micron, such as, for example, an opening with a dimension between 0.3 and 0.7 micron. In other implementations, opening 110 may be an opening with a dimension between 0.1 and 1 micron. In further implementations, opening 110 may be an opening with a dimension between 0.1 and 10 micron. It will be understood that opening 110 may be circular, oval, square, rectangular, or any other shape required by the implementation. The dimension of opening 110 may be a diameter or a width and will generally refer to the smallest lateral dimension of opening 110 to be filled. For example, in an implementation where opening 110 takes a rectangular shape having a width of 0.3 micron and a length of 2 micron, the dimension that is considered will be the width of 0.3 micron.

FIGS. 1D through 1H are sectional views of the portion of the superconducting integrated circuit 100c of FIG. 1C during stages of a deposition and reflow process for a second superconducting metal 112. Second superconducting metal 112 is deposited at an ambient temperature that is less than a melting temperature of second superconducting metal layer 112 such that second superconducting metal 112 fills opening 110 to form a connect 114 that conductively contacts the at least a portion of the first region of first superconducting metal layer 104. Second superconducting metal 112 further forms a second superconducting metal layer 116 that overlies dielectric layer 106 and connect 114. In some implementations second superconducting metal layer 112 is deposited by PVD in successive thin layers that are caused to reflow in the ambient temperature and fill opening 110 with few or no voids or cavities. Second superconducting metal 112 may be aluminum, and the aluminum may be deposited by PVD in layers at an ambient temperature that is less than 650° C., for example, between 100° C. and 520° C. Second superconducting metal 112 is deposited at a sufficiently high ambient temperature that the metal has sufficient mobility to fill opening 110 completely and form second superconducting metal layer 116 having a thickness as shown in FIG. 1H. Second superconducting metal layer 116 has a top surface 118h. In some implementations, top surface 118h may be sufficiently planar after deposition that additional layers may be formed directly on top surface 118h.

FIGS. 1I and 1J are sectional views of the portion of the superconducting integrated circuit 100h of FIG. 1H after an optional planarization stage. Planarizing second superconducting metal layer 112 may include chemical-mechanical polishing (CMP) to form a planar or substantially planar top surface 118. As shown in FIG. 1I, top surface 118i may be at a thickness from dielectric layer 106, or, as shown in FIG. 1J, top surface 118j may be planar with the top surface of dielectric layer 106. In some implementations, second superconducting metal layer 112 may be patterned. Top surface 118 may then receive additional layers to form additional elements of a superconducting integrated circuit.

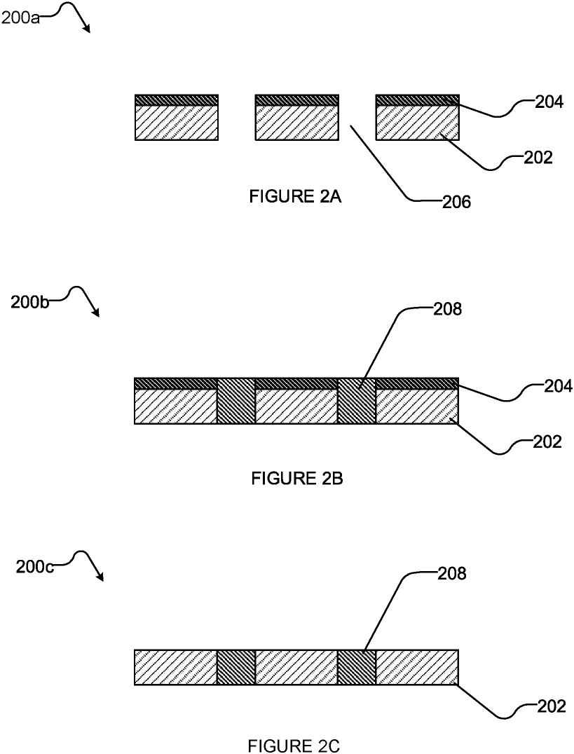

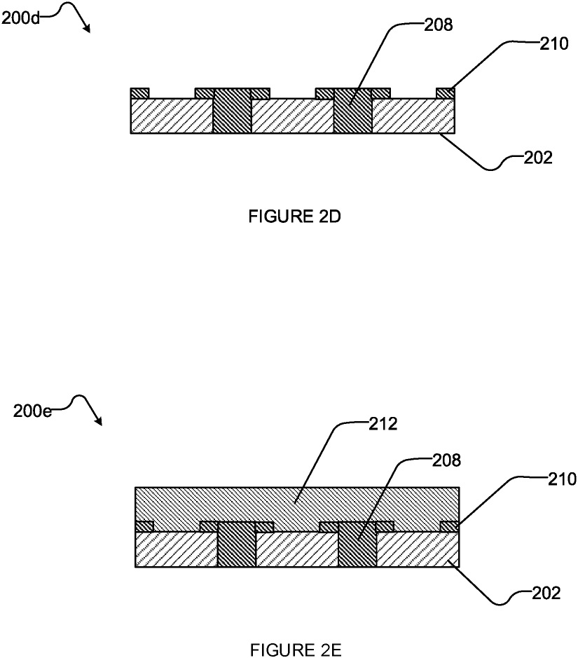

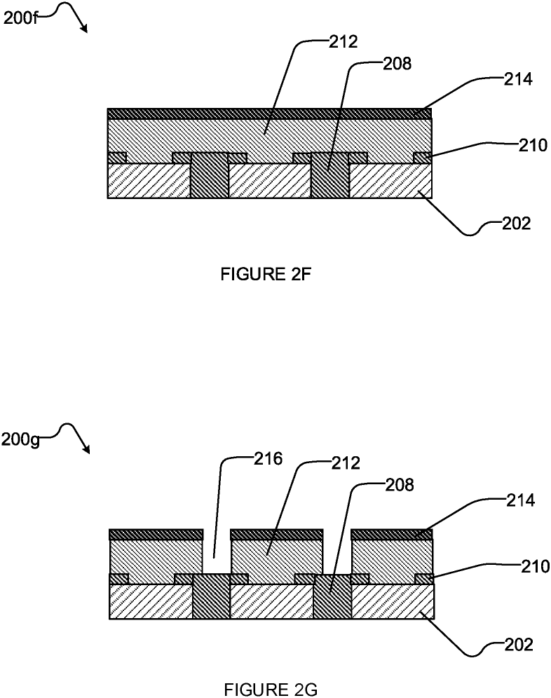

FIG. 2A is a sectional view of a portion of superconducting integrated circuit 200a having a first superconducting metal layer 202 and a deposited polish stop layer 204 deposited over at least a portion of first superconducting metal layer 202. First superconducting metal layer 202 and polish stop layer 204 have been patterned to form openings 206. In some implementations, polish stop layer 204 may not be included, and first superconducting metal layer 202 may be patterned to form openings 206 after deposition. In some implementations, first superconducting metal layer 202 may be aluminum, and may be deposited as a metal film. In some implementations, polish stop layer 204 may be a sacrificial film, and may be silicon nitride. Patterning of first superconducting metal layer 202 and deposited polish stop layer 204 may include masking and etching of the two layers. In some implementations this may include RIE.

FIG. 2B is a sectional view of the portion of superconducting integrated circuit 200a after deposition and planarization of a dielectric layer 208 in openings 206 to form superconducting integrated circuit 200b. Dielectric layer 208 may be planarized to have a top surface level with a top surface of polish stop layer 204. In some implementations, planarizing may include CMP. In some implementations, such as where polish stop layer 204 is not included, dielectric layer 208 may be deposited to fill openings 206 and cover a region of the top surface of first superconducting metal layer 202 and a top surface of dielectric layer 208 in openings 206, as shown in FIG. 2D. In some implementations dielectric layer 208 may be silicon dioxide, or other insulating interlayer dielectric materials.

FIG. 2C is a sectional view of the portion of superconducting integrated circuit 200b after removal of polish stop layer 204 to form superconducting integrated circuit 200c.

FIG. 2D is a sectional view of the portion of superconducting integrated circuit 200c after deposition and patterning of a second dielectric layer 210 to form superconducting integrated circuit 200d. Patterning of second dielectric layer 210 may include masking and etching, such as RIE.

FIG. 2E is a sectional view of the portion of superconducting integrated circuit 200d after deposition of second metal layer 212 to form superconducting integrated circuit 200e. Second metal layer 212 may be deposited at a temperature that is below the melting temperature of the second superconducting metal, but sufficiently high such that the second superconducting metal layer 212 will reflow to fill the openings formed in second dielectric layer 210 as shown, as well as to form a layer that overlies second dielectric layer 210 and the connect within the openings. In some implementations second metal layer 212 may be aluminum, and the temperature may be less than 650° C. In some implementations, the top surface of second metal layer 212 may be polished to smooth the top surface and select the thickness of second metal layer 212.

FIG. 2F is a sectional view of the portion of superconducting integrated circuit 200e after deposition of a second polish stop layer 214 over at least a portion of second superconducting metal layer 212 to form superconducting integrated circuit 200f. In some implementations, polish stop layer 214 may be a sacrificial film, and may be silicon nitride.

FIG. 2G is a sectional view of the portion of superconducting integrated circuit 200f after patterning of second metal layer 212 and polish stop layer 214 to form openings 216. In some implementations a third dielectric layer may be deposited to fill third openings 216. Patterning of second metal layer 212 and polish stop layer 214 may include masking and etching, such as RIE. Patterning may be done to stop at the material of dielectric layer 208.

In some implementations additional components may be formed by similar acts to those shown in FIGS. 2A through 2G.

It will be understood that the implementations described with respect to FIGS. 1A through 1J and FIGS. 2A through 2G are example configurations, and that methods 600 and 700 discussed below may be used to form superconducting integrated circuits having a variety of shapes and configurations.

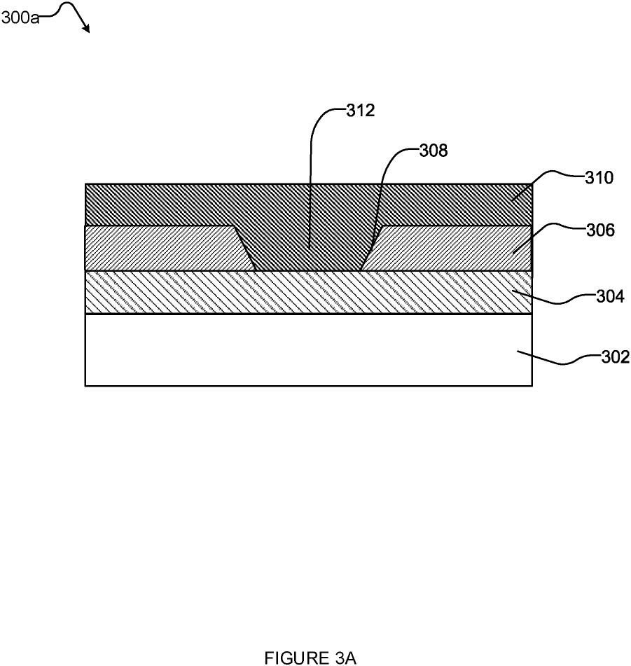

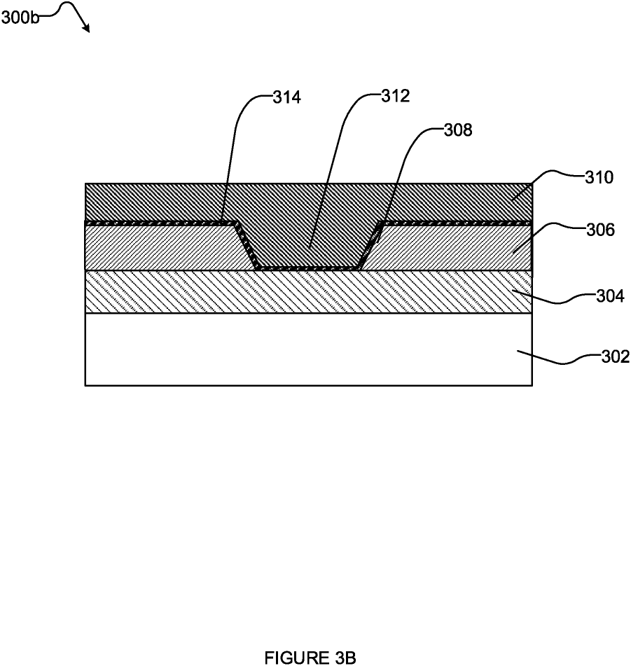

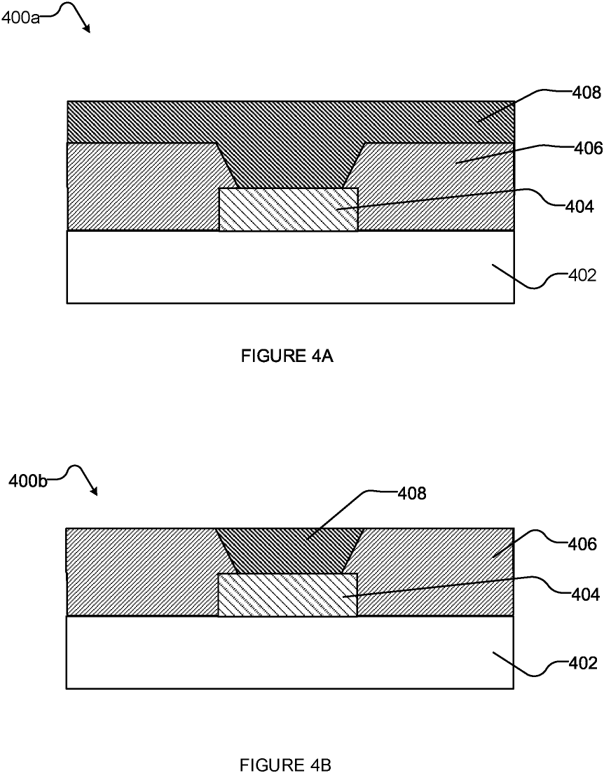

In the example implementation of FIG. 3A, superconducting integrated circuit 300a has a substrate 302 and a first superconducting metal layer 304 overlying at least a portion of substrate 302. A dielectric layer 306 is deposited to cover a region of first superconducting metal layer 304. In some implementations dielectric layer 306 may be deposited over the entire top surface of first superconducting metal layer 304 and then patterned to expose at least a portion of the top surface of first superconducting metal layer 304. In the implementation of superconducting integrated circuit 300, dielectric layer 306 has been patterned to define angled sidewalls 308. Second superconducting metal layer 310 is deposited at an ambient temperature that is less than a melting temperature of second superconducting metal layer 310 such that the second superconducting metal layer 310 fills the opening defined by angled sidewalls 308 to form an angled superconducting via 312 and a layer over dielectric layer 306 and angled superconducting via 312. Superconducting via 312 conductively contacts the exposed surface of first superconducting metal layer 304. First and second superconducting metal layers 304 and 310 may be formed of the same superconducting metal, such as aluminum.

In some implementations the material of second superconducting metal layer 310 may not adhere easily to the material of dielectric layer 306 and first superconducting metal layer 304, which may result in the second superconducting metal pulling away from the surface, leaving voids and uneven deposition of layer 310. In order to reduce or eliminate the second superconducting metal pulling away from the surfaces, a superconducting adhesion layer formed from a material that adheres more easily to superconducting metal layer 304 and dielectric layer 306 and to which second superconducting metal layer 310 adheres more easily may be included. FIG. 3B is a sectional view of an implementation of an angled superconducting via with a superconducting adhesion layer 314. It will be understood that any of the fabrication processes described herein may be amended to include depositing an adhesion layer line the sides or the sides and bottom of an opening prior to depositing a superconducting metal. The adhesion layer may, in some implementations, be formed from a titanium based material, such as pure titanium, titanium nitride, or titanium tungsten. Other superconducting materials may also be used.

FIGS. 4A and 4B are example implementations of an alternative angled superconducting via within superconducting integrated circuits 400a and 400b. Substrate 402 carries a first superconducting metal layer 404 that has been patterned to cover only a portion of substrate 402. Dielectric layer 406 has been deposited to cover substrate 402 and first superconducting metal layer 404, and then patterned to expose a portion of the top surface of first superconducting metal layer 404. Second superconducting metal layer 408 is deposited over dielectric layer 406 and first superconducting metal layer 404 at an ambient temperature that is less than a melting temperature of second superconducting metal layer 408 such that second superconducting metal layer 408 fills the opening in dielectric layer 406 and conductively contacts first superconducting metal layer 404, as well as forming an overlying layer. The top surface of the overlying layer of second superconducting metal layer 408 may be planarized to be smoothed. In the implementation of FIG. 4A, second superconducting metal layer 408 has been planarized to set a thickness of second superconducting metal layer 408. FIG. 4B is a sectional view of the alternative implementation of the angled superconducting via of FIG. 4A after planarization, where second superconducting metal layer 408 has been planarized to have a top surface that is level with the top surface of dielectric layer 406. In this implementation, an additional metal layer may be deposited over second superconducting metal layer 408 and dielectric layer 406, and second superconducting metal layer 408 may form an electrical connection between first superconducting metal layer 404 and the additionally deposited metal layer.

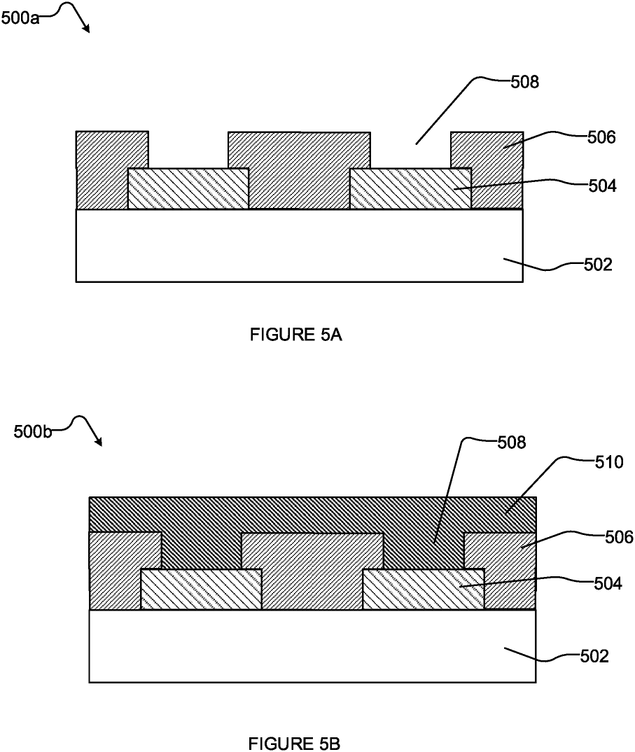

It will be understood that the features of the above superconducting integrated circuits may be combined as desired in a given application. For example, the implementations of FIGS. 4A and 4B have an angled via with a patterned first superconducting metal layer. In other implementations the patterned first superconducting metal layer may also be used with a via with straight sidewalls, such as in the example implementation of FIGS. 5A and 5b. FIGS. 5A and 5B exemplify an implementation of a straight superconducting via within superconducting integrated circuits 500a and 500b. A first superconducting metal layer 504 is deposited to directly or indirectly overlie at least a portion of substrate 502, and then is patterned to define individual superconducting metal components. A dielectric layer 506 is deposited to cover substrate 502 and the upper surface of first superconducting metal layer 504 and is patterned to expose at least a portion of the upper surface of first superconducting metal layer 504 and form an opening 508 to provide superconducting integrated circuit 500a. FIG. 5B is a sectional view of superconducting integrated circuit 500a after a second superconducting metal layer 510 is deposited at an ambient temperature that is less than a melting temperature of second superconducting metal layer 510 in order to form superconducting integrated circuit 500b. Second superconducting metal layer 510 fills openings 508 and conductively contacts at least a portion of the upper surface of first superconducting metal layer 504 and forms an overlying layer. Second superconducting metal layer 510 may then be planarized and/or patterned, and additional layers may be deposited. It will be understood that similar implementations may be formed on other layers of a superconducting integrated circuit such that the other layers overlie the substrate.

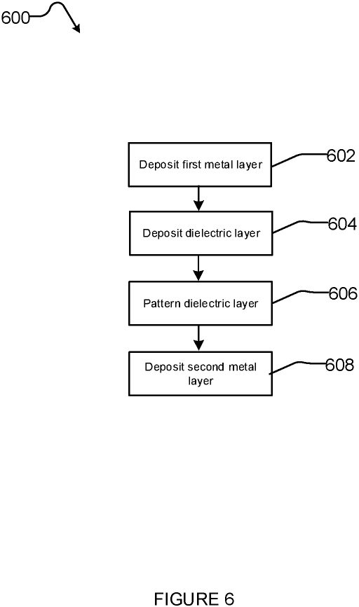

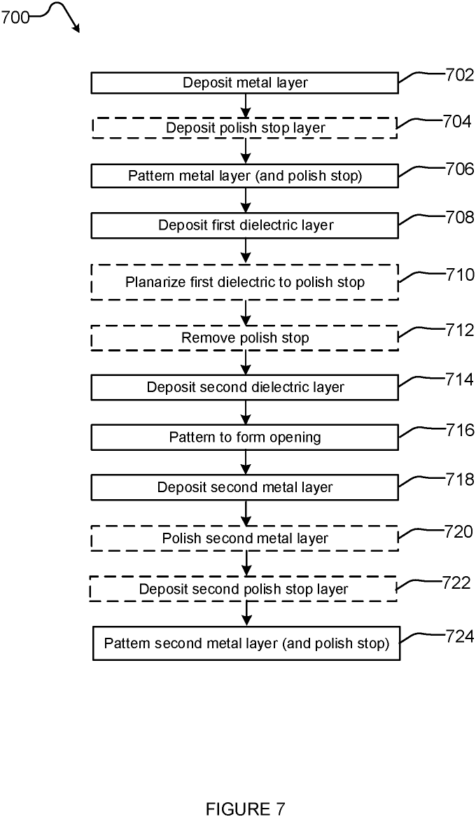

FIG. 6 is a flow chart illustrating a method 600 for forming a superconducting integrated circuit for a quantum processor in accordance with the present systems and methods. Method 600 may, for example, be used to form the superconducting integrated circuit components of FIGS. 1A through 1J. Method 600 includes acts 602-608, although in other implementations certain acts may be omitted, additional acts may be added, and/or the acts may be performed in different orders. Method 600 may be performed by, for example, integrated circuit fabrication equipment in response to an initiation of a fabrication process.

At 602, a first superconducting metal layer is deposited to directly or indirectly overlie at least a portion of a substrate. In some implementations, the first superconducting metal may be aluminum. The aluminum may be deposited directly on the substrate or over an intervening layer of an integrated circuit such as over a dielectric layer or over another metal layer. The aluminum may be deposited via a standard deposition process such as chemical vapor deposition or physical vapor deposition. In some implementations, the upper surface of the aluminum may be planarized using a chemical-mechanical planarization process.

At 604, a dielectric layer is deposited to cover a first region of the upper surface of the first superconducting metal layer. The dielectric material may include a non-oxide dielectric, such as silicon nitride and may be deposited by any deposition process, including CVD, PVD, and/or ALD.

At 606, the dielectric layer is patterned to expose at least a portion of the first region of the first superconducting metal layer and form an opening. The opening may have a dimension of greater than 0.3 micron, such as between 0.3 and 0.7 micron. In other implementations, the opening may have a dimension between 0.1 and 1 micron, or between 0.1 and 10 micron. As discussed above, the dimension of the opening may be a diameter or a width and will generally refer to the smallest lateral dimension of the opening to be filled.

At 608, a second superconducting metal layer is deposited at an ambient temperature that is less than a melting temperature of the second superconducting metal layer such that the second superconducting metal layer fills the opening and conductively contacts the at least a portion of the first region of the first superconducting metal layer. In some implementations, the second superconducting metal may be aluminum. In implementations where both the first and second metal layers are aluminum, an aluminum to aluminum interface may be formed. Deposition may occur at a temperature that is less than 650° C., such as between 100° C. and 520° C. Deposition may include depositing aluminum by physical vapor deposition (PVD) in layers and controlling the temperature to allow reflow of the aluminum into the opening.

After act 608, the method may end, or other fabrication acts may be performed. For example, the second superconducting metal layer may be planarized after being deposited, such as by chemical-mechanical polishing (CMP). The method may also begin again to form additional components within the quantum processor.

FIG. 7 is a flow chart illustrating one implementation of method 600 of FIG. 6 in accordance with the present systems and methods. Method 700 of FIG. 7 may, for example, be used to form the superconducting integrated circuit components of FIGS. 2A through 2G. Method 700 includes acts 702-724, although in other implementations certain acts may be omitted, additional acts may be added, and/or the acts may be performed in different orders. Acts 704, 710, 712, 720, and 722 are optional, and involve an optional polish stop layer. Method 700 may be performed by, for example, integrated circuit fabrication equipment in response to an initiation of a fabrication process.

At 702 a first superconducting metal layer is deposited. The first superconducting metal layer may be deposited as a metal film by techniques such as physical vapor deposition (PVD), chemical vapor deposition (CVD), plasma-enhanced PVD, plasma-enhanced CVD, and atomic layer deposition (ALD). In some implementations the first superconducting metal layer may be aluminum.

At 704 a polish stop layer is optionally deposited over at least a portion of the first superconducting metal layer prior to patterning the first superconducting metal layer. The polish stop layer may act as a sacrificial film in subsequent acts, and may, for example, be silicon nitride.

At 706 the first superconducting metal layer is patterned to form an opening. In implementations where a polish stop layer is deposited, both the first superconducting metal layer and the polish stop are patterned. Patterning may include subtractive patterning such as masking and etching. In some implementations the patterning may be done by reactive ion etching (RIE).

At 708 a dielectric layer is deposited to fill the opening in the first superconducting metal layer. The dielectric layer may, for example, be silicon dioxide.

At 710 the dielectric is planarized to have a top surface level with a top surface of the polish stop layer. In some implementations the dielectric may be planarized by CMP.

At 712 the polish stop layer may be removed. In some implementations, the polish stop layer may be removed by RIE.

At 714 another layer of dielectric may be deposited. In some implementations this dielectric material may be the same as the dielectric deposited at 708. In some implementations the dielectric may be silicon dioxide. In some implementations, acts 708 and 714 may be combined, such as for deposition techniques where the polish stop layer is not used. The dielectric layer is deposited to cover at least a first region of the top surface of the first superconducting metal layer, as well as a top surface of the dielectric layer deposited at 708.

At 716 the dielectric layer is patterned to expose at least a portion of the first region of the first superconducting metal layer and form an opening. In some implementations, patterning may include masking and etching techniques such as RIE. In some implementations the dielectric layer may be patterned to form an opening with a dimension of greater than 0.3 micron, such as an opening with a dimension between 0.3 and 0.7 micron. In other implementations, the opening may have a dimension between 0.1 and 1 micron, or between 0.1 and 10 micron. The dimension may be a diameter or a width and will generally refer to the smallest lateral dimension of the opening to be filled.

At 718 a second superconducting metal layer is deposited at an ambient temperature that is less than a melting temperature of the second superconducting metal layer such that the second superconducting metal layer fills the opening in the dielectric layer and conductively contacts the at least a portion of the first region of the first superconducting metal layer. The temperature is selected to be sufficiently high that the material of the second metal layer will reflow to fill the via openings formed in the dielectric layer. In some implementations, deposition may occur over multiple thin metal film layers deposited by techniques such as PVD, which are formed in order to reflow into the openings. In some implementations the second superconducting metal layer may be aluminum. In implementations where the second superconducting metal layer is aluminum, deposition may occur at a temperature that is less than 650° C., such as a temperature that is between 100° C. and 520° C.

At 720 the second superconducting metal layer is optionally polished to smooth the top surface of the second superconducting metal layer. In some implementations polishing may set the thickness of the second metal layer as desired. Act 720 may include planarizing the second superconducting metal layer, such as by chemical-mechanical polishing (CMP).

At 722 a second polish stop layer may optionally be deposited over at least a portion of the second superconducting metal layer. In some implementations the polish stop layer may act as a sacrificial film in subsequent acts, and may, for example, be silicon nitride.

At 724 the second superconducting metal layer is patterned to form features of a superconducting integrated circuit such as superconducting vias. In implementations where a polish stop layer has been deposited over the second superconducting metal layer, both the first superconducting metal layer and the polish stop are patterned. Patterning may include subtractive patterning such as masking and etching. In some implementations the patterning may be done by reactive ion etching (RIE). In some implementations the second polish stop layer and the second superconducting metal layer are patterned to form at least one third opening, which may then be filled by deposition of a third dielectric layer.

After 724, the method can be repeated, or other components of the superconducting integrated circuit may be formed. The method may end until, for example, it begins again to form a new superconducting integrated circuit. It will be understood that method 700 may be contained within a larger fabrication method, and act 702 may follow any number of prior fabrication acts, with any number of subsequent fabrication acts following act 724.

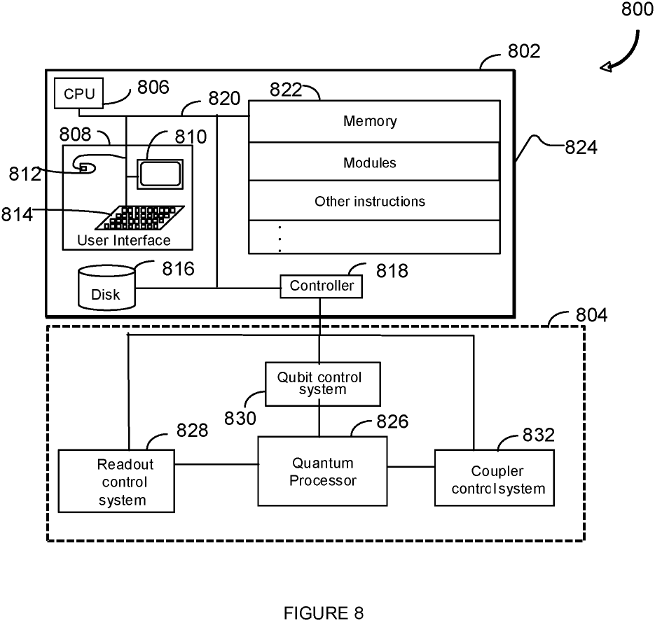

FIG. 8 illustrates a computing system 800 comprising a digital computer 802. The example digital computer 802 includes one or more digital processors 806 that may be used to perform classical digital processing tasks. Digital computer 802 may further include at least one system memory 822, and at least one system bus 820 that couples various system components, including system memory 822 to digital processor(s) 806. System memory 822 may store a set of modules 824.

The digital processor(s) 806 may be any logic processing unit or circuitry (for example, integrated circuits), such as one or more central processing units (“CPUs”), graphics processing units (“GPUs”), digital signal processors (“DSPs”), application-specific integrated circuits (“ASICs”), programmable gate arrays (“FPGAs”), programmable logic controllers (“PLCs”), etc., and / or combinations of the same.

In some implementations, computing system 800 comprises an analog computer 804, which may include one or more quantum processors 826. Quantum processor 826 may be at least one superconducting integrated circuit that includes microwave sensitive components within microwave shielding layers, components fabricated with low noise dielectrics, and other components fabricated using systems and methods described in the present application. Quantum processor 826 may include at least one integrated circuit that is fabricated using methods as described in greater detail herein. Digital computer 802 may communicate with analog computer 804 via, for instance, a controller 818. Certain computations may be performed by analog computer 804 at the instruction of digital computer 802, as described in greater detail herein.

Digital computer 802 may include a user input/output subsystem 808. In some implementations, the user input/output subsystem includes one or more user input/output components such as a display 810, mouse 812, and/or keyboard 814.

System bus 820 may employ any known bus structures or architectures, including a memory bus with a memory controller, a peripheral bus, and a local bus. System memory 822 may include non-volatile memory, such as read-only memory (“ROM”), static random-access memory (“SRAM”), Flash NAND; and volatile memory such as random-access memory (“RAM”) (not shown).

Digital computer 802 may also include other non-transitory computer-or processor-readable storage media or non-volatile memory 816. Non-volatile memory 816 may take a variety of forms, including: a hard disk drive for reading from and writing to a hard disk (for example, a magnetic disk), an optical disk drive for reading from and writing to removable optical disks, and/or a solid state drive (SSD) for reading from and writing to solid state media (for example NAND-based Flash memory). Non-volatile memory 816 may communicate with digital processor(s) via system bus 820 and may include appropriate interfaces or controllers 818 coupled to system bus 820. Non-volatile memory 816 may serve as long-term storage for processor- or computer-readable instructions, data structures, or other data (sometimes called program modules) for digital computer 802.

Although digital computer 802 has been described as employing hard disks, optical disks and/or solid-state storage media, those skilled in the relevant art will appreciate that other types of nontransitory and non-volatile computer-readable media may be employed. Those skilled in the relevant art will appreciate that some computer architectures employ nontransitory volatile memory and nontransitory non-volatile memory. For example, data in volatile memory may be cached to non-volatile memory. Or a solid-state disk that employs integrated circuits to provide non-volatile memory.

Various processor- or computer-readable instructions, data structures, or other data may be stored in system memory 822. For example, system memory 822 may store instruction for communicating with remote clients and scheduling use of resources including resources on the digital computer 802 and analog computer 804. Also, for example, system memory 822 may store at least one of processor executable instructions or data that, when executed by at least one processor, causes the at least one processor to execute the various algorithms to execute instructions. In some implementations system memory 822 may store processor- or computer-readable calculation instructions and/or data to perform pre-processing, co-processing, and post-processing to analog computer 804. System memory 822 may store a set of analog computer interface instructions to interact with analog computer 804.

Analog computer 804 may include at least one analog processor such as quantum processor 826. Analog computer 804 may be provided in an isolated environment, for example, in an isolated environment that shields the internal elements of the quantum computer from heat, magnetic field, and other external noise. The isolated environment may include a refrigerator, for instance a dilution refrigerator, operable to cryogenically cool the analog processor, for example to temperature below approximately 1K.

Analog computer 804 may include programmable elements such as qubits, couplers, and other devices. Qubits may be read out via readout system 828. Readout results may be sent to other computer- or processor-readable instructions of digital computer 802. Qubits may be controlled via a qubit control system 830. Qubit control system 830 may include on-chip digital to analog converters (DACs) and analog lines that are operable to apply a bias to a target device. Couplers that couple qubits may be controlled via a coupler control system 832. Couple control system 832 may include tuning elements such as on-chip DACs and analog lines. Qubit control system 830 and coupler control system 832 may be used to implement a quantum annealing schedule as described herein on analog processor 804. Programmable elements may be included in quantum processor 826 in the form of an integrated circuit. Qubits and couplers may be positioned in layers of the integrated circuit that comprise a first material. Other devices, such as readout control system 828, may be positioned in other layers of the integrated circuit that comprise a second material.

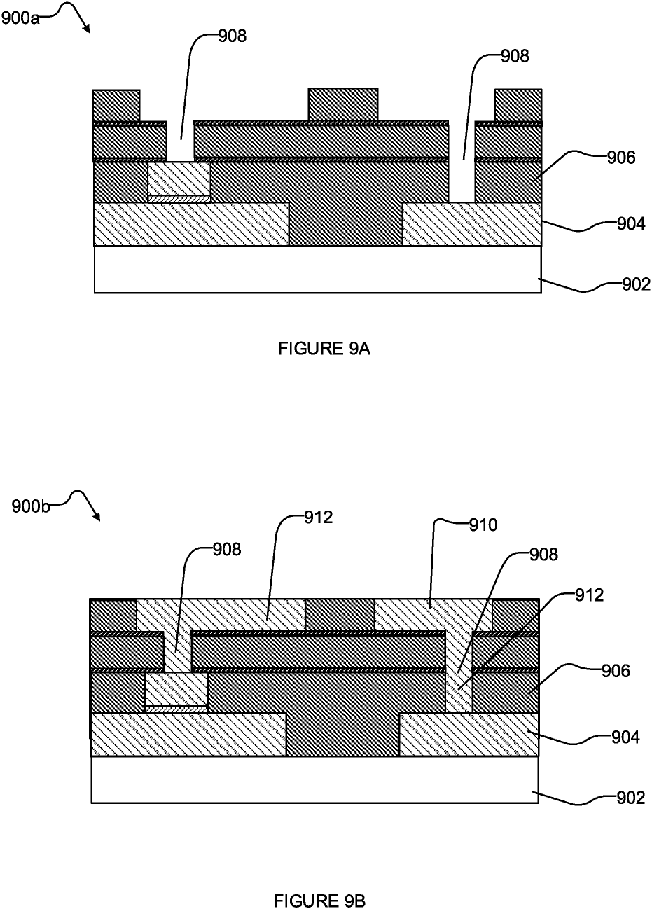

It will be understood that the methods described herein may be used to form a variety of different components of superconducting integrated circuits. In the implementations shown in FIG. 9A and FIG. 9B, the methods may be combined with a dual damascene process. FIG. 9A shows an example implementation of a superconducting integrated circuit 900a that has been patterned to form openings 908. A first superconducting metal layer 904 is deposited to directly or indirectly overlie at least a portion of substrate 902, and then is patterned to define individual superconducting metal components. A dielectric layer 906 is deposited to cover substrate 902 and the upper surface of first superconducting metal layer 904 and is patterned to expose at least a portion of the upper surface of first superconducting metal layer 904 and form openings 908 to provide superconducting integrated circuit 900a.

FIG. 9B is a sectional view of superconducting integrated circuit 900a after a second superconducting metal layer 910 is deposited at an ambient temperature that is less than a melting temperature of second superconducting metal layer 910 in order to form superconducting integrated circuit 900b. Second superconducting metal layer 910 fills openings 908 and conductively contacts at least a portion of the upper surface of first superconducting metal layer 904. Second superconducting metal layer 910 may have be planarized and/or patterned after deposition, and additional layers may be deposited. In the example implementation of FIG. 9B, first superconducting metal layer 904 is a first wiring layer, and second superconducting metal layer 910 makes up both a superconducting via 912 and a second wiring layer 914.

FIG. 10A is a sectional view of a portion of a superconducting integrated circuit 1000a after metal layer 1004 is deposited to either directly or indirectly overlie at least a portion of substrate 1002.

FIG. 10B is a sectional view of superconducting integrated circuit 1000a after planarization of first superconducting metal layer 1004 and deposition and patterning of dielectric layer 1006 to form superconducting integrated circuit 1000b. As discussed above, planarization of first superconducting metal layer 1004 may include CMP. Dielectric layer 1006 is deposited on surface 1008 of first superconducting metal layer 1004 and patterned to form opening 1010.

As discussed above, in some material combinations, the second superconducting metal may not readily or reliably adhere to the material of the first superconducting layer and/or the material of the dielectric layer. In some implementations, it may be beneficial to provide an adhesion or seed layer of the second superconducting material that is deposited at a low ambient temperature relative to the remainder of the second superconducting material that forms the layer, with both ambient temperatures being less than a melting temperature of the second superconducting metal. In some implementations, such as where the second superconducting metal is aluminum, the grain size of the aluminum may increase as the deposition temperature is increased, resulting in increased problems with adherence between the materials. In some implementations, it may be beneficial to deposit a first adhesion or seed layer of the aluminum at a cool temperature prior to depositing at a higher temperature. The lower temperature aluminum may adhere easily to the metal and dielectric layers, and the higher temperature aluminum may adhere easily to the lower temperature aluminum.

FIG. 10C is a sectional view of superconducting integrated circuit 1000b after a low temperature reflow deposition of a first portion 1012a to form superconducting integrated circuit 1000c. In some implementations, first portion 1012a may be aluminum that is deposited at an ambient temperature that is between 100° C. and 300° C.

FIG. 10D is a sectional view of superconducting integrated circuit 1000c during a high temperature reflow deposition of a second portion 1012b to form superconducting integrated circuit 1000d. In some implementations, second portion 1012b may be aluminum that is deposited at an ambient temperature that is between 450° C. and 650° C. First portion 1012a and second portion 1012b are collectively referred to herein as second superconducting metal layer 1012.

FIG. 10E is a sectional view of superconducting integrated circuit 1000d after completion of high temperature reflow deposition and polishing of the second metal layer to form superconducting integrated circuit 1000e. In some implementations, an interface 1022 (e.g., a transition region) between first portion 1012a and second portion 1012b is discernable as a result of the formation of first and second portions 1012a and 1012b at different ambient temperatures. For example, in some implementations, the grain size of aluminum at one region or layer (e.g., first portion 1012a) can be different from the grain size of aluminum at another region or layer (e.g., second portion 1012b) based on the ambient temperatures at which the aluminum comprising those regions or layers was deposited, resulting in a discernable interface in transitioning between different aluminum grain sizes that may be detected with appropriate techniques. It will be understood that this interface may include a finite region of mixing (e.g., a transition region) between the first portion 1012a and second portion 1012b.

In some implementations chemistry used in patterning metal layers may cause contamination of the metal, which may result in adverse effects such as noise on the processor during use. In one implementation, etching chemistry that includes Fluorine may contaminate aluminum and create noise on the processor. In order to reduce or eliminate this contamination, a passivation layer may be applied over the metal layer prior to the patterning operation, such that the top surface of the metal is never exposed to the potential contaminant. The superconducting barrier layer or passivation layer is deposited overlying the second superconducting metal layer and the second superconducting metal layer and the superconducting barrier layer are patterned together.

FIG. 10F is a sectional view of superconducting integrated circuit 1000e after deposition of a passivation layer 1016 to form superconducting integrated circuit 1000f.

FIG. 10G is a sectional view of superconducting integrated circuit 1000f after patterning of second superconducting metal layer 1012 (made up of 1012a and 1012b) and passivation layer 1016 to form superconducting integrated circuit 1000g.

FIG. 10H is a sectional view of superconducting integrated circuit 1000g after removal of passivation layer 1016 to form superconducting integrated circuit 1000h.

Referring to FIGS. 1A through 1J, in some implementations the described acts may be performed at a relatively low and uniform ambient temperature, such as, for example, an ambient temperature that is between 100° C. and 300° C. In contrast, referring to FIGS. 10A through 10H, in other implementations the described acts may be performed at two different temperatures, one which is relatively low, such as, for example, an ambient temperature that is between 100° C. and 300° C., and one which is relatively high but still below the melting point of the relevant superconducting metal, such as, for example, an ambient temperature that is between 450° C. and 650° C. In some implementations, both temperature ranges may be used at different portions of the circuit.

FIG. 10I is a sectional view of a portion of a superconducting integrated circuit 1000i having both high temperature and low temperature superconducting metal layers. It will be understood that while in FIG. 10I shows a connect and wiring layer with a two temperature process 1018 with the connect in communication with a metal layer 1004, and a connect and wiring layer with a one temperature process 1020 with the connect in communication with connect and wiring layer 1018, the order of the components 1018 and 1020 may be reversed in other implementations, or components 1018 and 1020 may be formed in separate portions of a superconducting integrated circuit and not be directly in communication with each other.

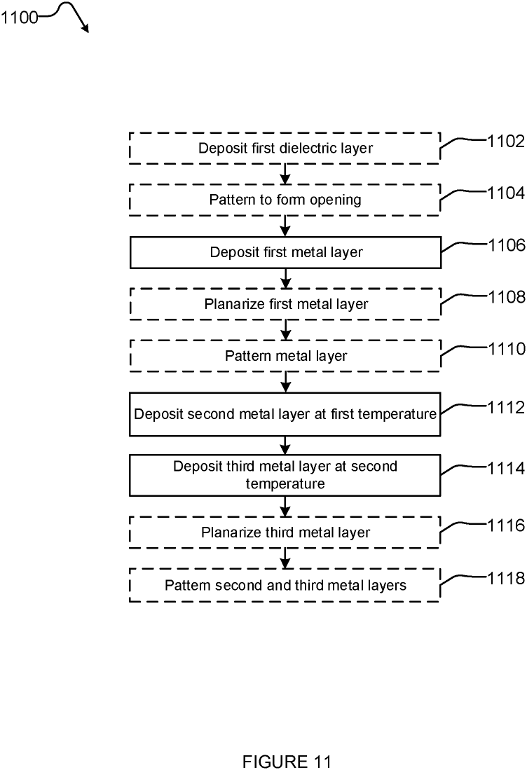

FIG. 11 is a flow chart illustrating a method 1100 for forming a superconducting integrated circuit for a quantum processor in accordance with the present systems and methods. Method 1100 may, for example, be used to form the superconducting integrated circuit components of FIGS. 10A through 10I. Method 1100 includes acts 1102-1118, although in other implementations certain acts may be omitted, additional acts may be added, and/or the acts may be performed in different orders. Method 1100 may be performed by, for example, integrated circuit fabrication equipment in response to an initiation of a fabrication process.

At 1102, a first dielectric layer may be deposited, for example, over a superconducting metal layer, as discussed above.

At 1104, the first dielectric layer may be patterned to form an opening, for example, to expose the surface of the underlying superconducting metal layer.

At 1106, a first superconducting metal is depositing at a first ambient temperature that is less than a melting temperature of the first superconducting metal such that the first superconducting metal fills an opening in a first dielectric layer to form a first connect that conductively contacts a conductive layer underlying the first dielectric layer and forms a first superconducting metal layer that overlies the first dielectric layer and the first connect.

At 1108, the first superconducting metal layer is optionally planarized, such as with a chemical-mechanical planarization process.

At 1110, the first superconducting metal layer is optionally patterned, such as to form wiring.

At 1112, the first superconducting metal is deposited at a second ambient temperature that is less than a melting temperature of the first superconducting metal such that the first superconducting metal forms an adhesion layer lining an opening in a second dielectric layer and overlying the second dielectric layer.

At 1114, the first superconducting metal is deposited at a third ambient temperature that is less than a melting temperature of the first superconducting metal and greater than the second ambient temperature to form a fill layer to cover the adhesion layer such that the adhesion layer and the fill layer fill the opening in the second dielectric layer to form a second connect that conductively contacts a conductive layer underlying the second dielectric and form a second superconducting metal layer that overlies the second dielectric layer and the first connect.

In some implementations the first ambient temperature and the second ambient temperature may be the same, and may be, for example, between 100° C. and 300° C. The third ambient temperature is higher than the second ambient temperature, and may be, for example, between 450° C. and 650° C.

At 1116, the third metal layer may optionally be planarized, such as with CMP.

At 1118, the second and third metal layers may be patterned, such as to form wiring.

After 1118, the method can be repeated, or other components of the superconducting integrated circuit may be formed. The method may end until, for example, it begins again to form a new superconducting integrated circuit. It will be understood that method 1100 may be contained within a larger fabrication method, and act 1102 may follow any number of prior fabrication acts, with any number of subsequent fabrication acts following act 1118.

In some implementations, act 1106 may occur prior to acts 1112 and 1114. In some implementations, one portion of an integrated circuit may be fabricated at a lower temperature, and may use act 1106, and another portion of the integrated circuit may be fabricated at a higher temperature and may use acts 1112 and 1114. For example, where components of the superconducting integrated circuit are temperature sensitive during fabrication, the higher temperature two stage process of acts 1112 and 1114 may be used in lower levels of the superconducting integrated circuit, and then the lower temperature one stage process of act 1106 may be used on higher levels where the temperature sensitive devices are formed.

Other examples of superconducting integrated circuits that may be combined with the methods described herein can be found in U.S. Pat. No. 9,768,371.

The above described method(s), process(es), or technique(s) could be implemented by a series of processor readable instructions stored on one or more nontransitory processor-readable media. Some examples of the above described method(s), process(es), or technique(s) method are performed in part by a specialized device such as an adiabatic quantum computer or a quantum annealer or a system to program or otherwise control operation of an adiabatic quantum computer or a quantum annealer, for instance a computer that includes at least one digital processor. The above described method(s), process(es), or technique(s) may include various acts, though those of skill in the art will appreciate that in alternative examples certain acts may be omitted and/or additional acts may be added. Those of skill in the art will appreciate that the illustrated order of the acts is shown for exemplary purposes only and may change in alternative examples. Some of the exemplary acts or operations of the above described method(s), process(es), or technique(s) are performed iteratively. Some acts of the above described method(s), process(es), or technique(s) can be performed during each iteration, after a plurality of iterations, or at the end of all the iterations.

The above description of illustrated implementations, including what is described in the Abstract, is not intended to be exhaustive or to limit the implementations to the precise forms disclosed. Although specific implementations of and examples are described herein for illustrative purposes, various equivalent modifications can be made without departing from the spirit and scope of the disclosure, as will be recognized by those skilled in the relevant art. The teachings provided herein of the various implementations can be applied to other methods of quantum computation, not necessarily the exemplary methods for quantum computation generally described above.

The various implementations described above can be combined to provide further implementations. All of the commonly assigned U.S. Pat. application publications, U.S. Pat. applications, foreign patents, and foreign patent applications referred to in this specification and/or listed in the Application Data Sheet are incorporated herein by reference, in their entirety, including but not limited to: U.S. Pat. No. 9,768,371, issued Sep. 19, 2017, entitled “SYSTEMS AND METHODS FOR FABRICATION OF SUPERCONDUCTING INTEGRATED CIRCUITS”; and U.S. Pat. Application No. 63/042,865, filed Jun. 23, 2020, entitled “SYSTEMS AND METHODS FOR FABRICATING SUPERCONDUCTING INTEGRATED CIRCUITS.”

These and other changes can be made to the implementations in light of the above-detailed description. In general, in the following claims, the terms used should not be construed to limit the claims to the specific implementations disclosed in the specification and the claims but should be construed to include all possible implementations along with the full scope of equivalents to which such claims are entitled. Accordingly, the claims are not limited by the disclosure.

What is claimed is:

1. A method of forming a superconducting integrated circuit for a quantum processor, the method comprising:
depositing a first superconducting metal to form a first superconducting metal layer that overlies at least a portion of a substrate, the first superconducting metal layer comprising an upper surface having a first region;
depositing a dielectric layer to cover the first region of the first superconducting metal layer;
patterning the dielectric layer to expose at least a portion of the first region of the first superconducting metal layer and form an opening having sides defined by the dielectric layer and a bottom defined by the exposed at least a portion of the first region of the first superconducting metal layer; and
depositing a second superconducting metal at an ambient temperature that is less than a melting temperature of the second superconducting metal such that the second superconducting metal fills the opening to form a connect that conductively contacts the at least a portion of the first region of the first superconducting metal layer and forms a second superconducting metal layer that overlies the dielectric layer and the connect.

2. The method of claim 1, further comprising depositing an adhesion layer to line at least the sides of the opening prior to depositing the second superconducting metal.

3. The method of any one of claims 1 and 2, further comprising planarizing the first superconducting metal layer.

4. The method of any one of claims 1 through 3, further comprising planarizing the second superconducting metal layer.

5. The method of claim 4, wherein planarizing the second superconducting metal layer comprises chemical-mechanical polishing (CMP).

6. The method of any one of claims 1 through 5, wherein patterning the dielectric layer to form an opening comprises patterning the dielectric layer to form an opening with a dimension of greater than 0.1 micron.

7. The method of any one of claims 1 through 6, wherein depositing a second superconducting metal comprises depositing aluminum.

8. The method of claim 7, wherein depositing a second superconducting metal at an ambient temperature that is less than a melting temperature of the second superconducting metal comprises depositing at an ambient temperature that is less than 650° C.

9. The method of claim 8, wherein depositing a second superconducting metal at an ambient temperature that is less than a melting temperature of the second superconducting metal comprises depositing at an ambient temperature that is between 100° C. and 520° C.

10. The method of claim 7, wherein depositing a second superconducting metal at an ambient temperature that is less than a melting temperature of the second superconducting metal comprises depositing a first portion at an ambient temperature that is between 100° C. and 300° C. and depositing a second portion at an ambient temperature that is between 450° C. and 650° C.

11. The method of claim 7, wherein depositing the second superconducting metal comprises depositing aluminum by physical vapor deposition (PVD).

12. The method of claim 7, wherein depositing the first superconducting metal comprises depositing aluminum.

13. The method of any one of claims 1 through 12, wherein:
depositing a first superconducting metal comprises depositing a first wiring layer; and
depositing a second superconducting metal comprises depositing a via and a second wiring layer.

14. The method of any one of claims 1 through 13, further comprising:
after depositing the first superconducting metal layer, patterning the first superconducting metal layer to form an additional opening;
depositing an additional dielectric layer to fill the additional opening; and
depositing the dielectric layer to cover the first region of the first superconducting metal layer and a top surface of the additional dielectric layer.

15. The method of claim 14, further comprising:
prior to patterning the first superconducting metal layer, depositing a polish stop layer over the at least a portion of the first superconducting metal layer; and
wherein patterning the first superconducting metal layer further comprises patterning the first superconducting metal layer and the polish stop layer.

16. The method of claim 15, further comprising:
after depositing the additional dielectric layer to fill the additional opening, planarizing the additional dielectric layer to have a top surface level with a top surface of the polish stop layer; and
removing the polish stop layer.

17. The method of claim 16, further comprising:
depositing a second polish stop layer over at least a portion of the second superconducting metal layer;
patterning the second polish stop layer and the second superconducting metal layer to form a third opening; and
depositing a third dielectric layer to fill the third opening.

18. The method of any one of claims 1 through 17, further comprising depositing a superconducting barrier layer overlying the second superconducting metal layer and patterning the second superconducting metal layer and the superconducting barrier layer.

19. A method of forming a superconducting integrated circuit for a quantum processor, the method comprising:
depositing a first superconducting metal at a first ambient temperature that is less than a melting temperature of the first superconducting metal such that the first superconducting metal fills an opening in a first dielectric layer to form a first connect that conductively contacts a conductive layer underlying the first dielectric layer and forms a first superconducting metal layer that overlies the first dielectric layer and the first connect;
depositing the first superconducting metal at a second ambient temperature that is less than a melting temperature of the first superconducting metal such that the first superconducting metal forms an adhesion layer lining an opening in a second dielectric layer and overlying the second dielectric layer; and
depositing the first superconducting metal at a third ambient temperature that is less than a melting temperature of the first superconducting metal and greater than the second ambient temperature to form a fill layer to cover the adhesion layer such that the adhesion layer and the fill layer fill the opening in the second dielectric layer to form a second connect that conductively contacts a conductive layer underlying the second dielectric and form a second superconducting metal layer that overlies the second dielectric layer and the first connect.

20. The method of claim 19, wherein depositing a first superconducting metal at an ambient temperature that is less than a melting temperature of the first superconducting metal comprises depositing at an ambient temperature that is between 100° C. and 300° C., depositing the first superconducting metal at a second ambient temperature that is less than a melting temperature of the first superconducting metal comprises depositing at an ambient temperature that is between 100° C. and 300° C., and depositing the first superconducting metal at a third ambient temperature that is less than a melting temperature of the first superconducting metal comprises depositing at an ambient temperature that is between 450° C. and 650° C.

21. A superconducting integrated circuit comprising:
a substrate;
a first metal layer comprising a first metal that superconducts below a first critical temperature, the first metal layer overlying at least a portion of the substrate, the first metal layer comprising an upper surface having a first region;
a dielectric layer overlying at least a portion of the first metal layer, the dielectric layer comprising an opening that exposes at least a portion of the first region of the first metal layer and has sides defined by the dielectric layer and a bottom defined by the exposed at least a portion of the first region of the first metal layer;
a second metal layer comprising a second metal that superconducts below a second critical temperature, the second metal layer lining at least the sides of the opening, the second metal layer comprising an adhesion layer; and
a third metal layer comprising the second metal, the third metal layer overlying at least a portion of the dielectric layer and filling the opening, the third metal layer in conductive contact with the at least a portion of the first region of the first metal layer.

22. The superconducting integrated circuit of claim 21, wherein the second metal comprises aluminum.

23. The superconducting integrated circuit of any one of claims 21 and 22, wherein the first metal comprises aluminum.

24. The superconducting integrated circuit of any one of claims 21 through 23, wherein the opening has a dimension of greater than 0.1 micron.

25. The superconducting integrated circuit of any one of claims 21 through 24, wherein the first metal layer comprises a first wiring layer, and the second and third metal layers comprise a via and a second wiring layer.

26. The superconducting integrated circuit of any one of claims 21 through 25, wherein an interface between the second metal layer and the third metal layer is discernable.
